(19) United States
(12) Patent Application Publication
(10) Pub. No.: US 2012/0291834 A1
(43) Pub. Date: Nov. 22, 2012

(54) SOLAR BATTERY MODULE AND MANUFACTURING METHOD THEREOF

(76) Inventors: Shih-Wei Lee, Kaohsiung City (TW); Yen-Chun Chen, Taoyuan County (TW)

(21) Appl. No.: 13/205,641

(22) Filed: Aug. 9, 2011

(30) Foreign Application Priority Data
May 20, 2011 (TW) 100117747

(51) Int. Cl. H01L 31/05; H01L 31/18

(52) U.S. Cl. 136/244; 438/98; 257/E31.124

(57) ABSTRACT

A solar battery module includes a substrate, a plurality of first striped electrodes formed on the substrate, and a plurality of striped photoelectric transducing layers respectively formed on the corresponding first striped electrode. The solar battery module further includes a plurality of second striped electrodes respectively formed on the corresponding striped photoelectric transducing layer, a plurality of insulating layers respectively formed between the adjacent first striped electrodes, the adjacent photoelectric transducing layers, and the adjacent second striped electrodes, and a plurality of conducting layers respectively formed between the adjacent insulating layers. Wherein, a width of each photoelectric transducing layer along a first direction is smaller than a width of each striped first striped electrode corresponding to the photoelectric transducing layer along the first direction, and the plurality of first striped electrodes and the plurality of second striped electrodes are in series connection along the first direction.

### BACKGROUND OF THE INVENTION

1. Field of the Invention

The invention relates to a solar battery module, and more particularly, to a solar battery module capable of generating heavy current and customizing easily.

2. Description of the Prior Art

Please refer to FIG. 1. FIG. 1 is a diagram of a solar battery module 10 in the prior art. The conventional solar battery module 10 includes a substrate 12, a conducting layer 14, a photoelectric transducing layer 16 and an electrode 18. A manufacturing method of the conventional solar battery module 10 is forming the conducting layer 14 on the substrate 12, removing parts of the conducting layer 14 to expose parts of the substrate 12 to form a plurality of striped conducting layers 14, forming the photoelectric layer 16 on the substrate 12 and the striped conducting layers 14, removing parts of the photoelectric transducing layer 16 to expose parts of the striped conducting layers 14 for forming a plurality of striped photoelectric transducing layers 16, forming the electrode 18 on the striped conducting layer 14 and the striped photoelectric transducing layer 16, and removing parts of the electrode 18 to expose parts of the striped conducting layers 14, so as to form a plurality of striped electrodes 18. Thus, each striped electrode 18 is electrically connected to the corresponding striped conducting layer 14 for setting a plurality of solar batteries 101 in series connection, so that the conventional solar battery module 10 can generate heavy current. A conductive medium, such as a metal thin film, is utilized to set the plurality of solar batteries 101 in parallel connection, so that the conventional solar battery module 10 can generate heavy voltage.

In addition, an area for the conductive medium is reserved on the substrate 12, and superficial measure of the photoelectric transducing layer 16 is decreased, which means photoelectric transducing efficiency of the conventional solar battery module 10 is also decreased. The plurality of solar batteries 101 of the conventional solar battery module 10 can be set in series connection and parallel connection by string and lay-up method for achieving customer's demand, such as heavy voltage intensity and heavy current intensity. Therefore, photoelectric transducing efficiency of the conventional solar battery module 10 is constrained due to lower effective measure of the photoelectric transducing layer 16, and can not be customized according to actual demand. A manufacturing method of a thin film solar battery is disclosed in US patent publication no. US 2007/0079866. An insulating layer is formed between the adjacent solar batteries in the cited reference. However, a conducting layer is easily to contact the adjacent conducting layer due to misalignment, an expensive alignment apparatus is necessary for forming the conducting layer accurately to prevent short, and a gap between the adjacent solar batteries is widened for preventing the short.

### SUMMARY OF THE INVENTION

The invention provides solar battery module capable of generating heavy current and customizing easily for solving above drawbacks.

According to the claimed invention, a solar battery module includes a substrate, a plurality of first striped electrodes separately formed on the substrate, and a plurality of striped photoelectric transducing layers respectively formed on the corresponding first striped electrode. A width of each striped photoelectric transducing layer along a first direction is substantially smaller than a width of the corresponding first striped electrode along the first direction. The solar battery module further includes a plurality of second striped electrodes respectively formed on the corresponding striped photoelectric transducing layer, and a plurality of insulating layers respectively formed between the adjacent first striped electrodes, the adjacent striped photoelectric transducing layers and the adjacent second striped electrodes. The insulating layer covers a first end of the corresponding first striped electrode, a first end and a second end of the corresponding striped photoelectric transducing layer, and a first end and a second end of the corresponding second striped electrode, and the insulating layer does not cover parts of the substrate and a second end of the corresponding first striped electrode. The solar battery module further includes a plurality of conducting layers respectively formed between the adjacent insulating layers. Each conducting layer contacts an upper surface of the second striped electrode and the adjacent first striped electrode, so that the first striped electrode and the second striped electrode are in series connection along the first direction.

According to the claimed invention, the first end of each striped photoelectric transducing layer aligns with the first end of the corresponding first striped electrode, and the second end of each striped photoelectric transducing layer does not align with the second end of the corresponding first striped electrode to expose the parts of the first striped electrode.

According to the claimed invention, the first end and the second end of each second striped electrode respectively align with the first end and the second end of the corresponding striped photoelectric transducing layer.

According to the claimed invention, the solar battery module further includes a buffer layer formed between the striped photoelectric transducing layer and the second striped electrode, and the buffer layer is made of zinc sulphide material and intrinsic zinc oxide material.

According to the claimed invention, the substrate is a flexible substrate, and the flexible substrate is selected from a group consisting of aluminum thin foil and stainless steel.

According to the claimed invention, the solar battery module further comprises a barrier layer disposed between the substrate and the first striped electrode, and the barrier layer is selected from a group consisting of silicon dioxide material, aluminum oxide material, silicone nitride material, and combination thereof.

According to the claimed invention, the substrate is a flexible substrate, and the flexible substrate is made of polyimide material.

According to the claimed invention, the first striped electrode is made of molybdenum material.

According to the claimed invention, the striped photoelectric transducing layer is made of copper indium gallium selenide material.

According to the claimed invention, the second striped electrode is a transparent conductive layer made of aluminum zinc oxide or tin-doped indium oxide material.

According to the claimed invention, a method of manufacturing a solar battery module includes forming a first electrode layer on a substrate, forming a photoelectric transducing layer on the first electrode layer, forming a second electrode layer on the photoelectric transducing layer, removing parts of the second electrode layer, parts of the photoelectric transducing layer and parts of the first electrode layer, so as to form a plurality of first striped electrodes, a plurality of striped photoelectric transducing layers and a plurality of second striped electrodes separately arranged in parallel along a first direction, and to expose parts of the substrate and parts of the first striped electrode, forming a plurality of insulating layers between the adjacent first striped electrodes, the adjacent striped photoelectric transducing layers and the adjacent second striped electrodes, so that the insulating layer covers a first end of the corresponding first striped electrode, a first end and a second end of the corresponding striped photoelectric transducing layer, and a first end and a second end of the corresponding second striped electrode, and the insulating layer does not cover parts of the substrate and a second end of the corresponding first striped electrode, and forming a plurality of conducting layers respectively between the adjacent insulating layers, each conducting layer contacting an upper surface of the second striped electrode and the adjacent first striped electrode, so that the first striped electrode and the second striped electrode are in series connection along the first direction.

The plurality of solar batteries can be formed by segmenting the solar battery module of the invention directly. Two insulating layers can be respectively disposed on edges of each solar battery adjacent to the other solar batteries, so that the conducting layer does not contact the adjacent conducting layer and the electrode for preventing short in manufacturing procedure by protection of the insulating layer, and each solar battery can be electrically connected to the adjacent solar battery by the conducting layer. Thus, the solar battery module with smaller gaps between the solar batteries can be manufactured in the invention without the expensive alignment apparatus. The effective photoelectric transducing area of the solar battery module is controlled easily by the manufacturing method of the invention, so as to manufacture the solar battery module with the heavy current and the heavy voltage according to user's demand.

These and other objectives of the invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a solar battery module in the prior art.

FIG. 2 is a diagram of a solar battery module according to a preferred embodiment of the invention.

FIG. 3 is a diagram of the solar battery module according to the other embodiment of the invention.

FIG. 4 is a flow chart of the method of manufacturing the solar battery module according to the preferred embodiment of the invention.

FIG. 5 to FIG. 9 are sectional views of the solar battery module in different procedures along the first direction according to the preferred embodiment of the invention.

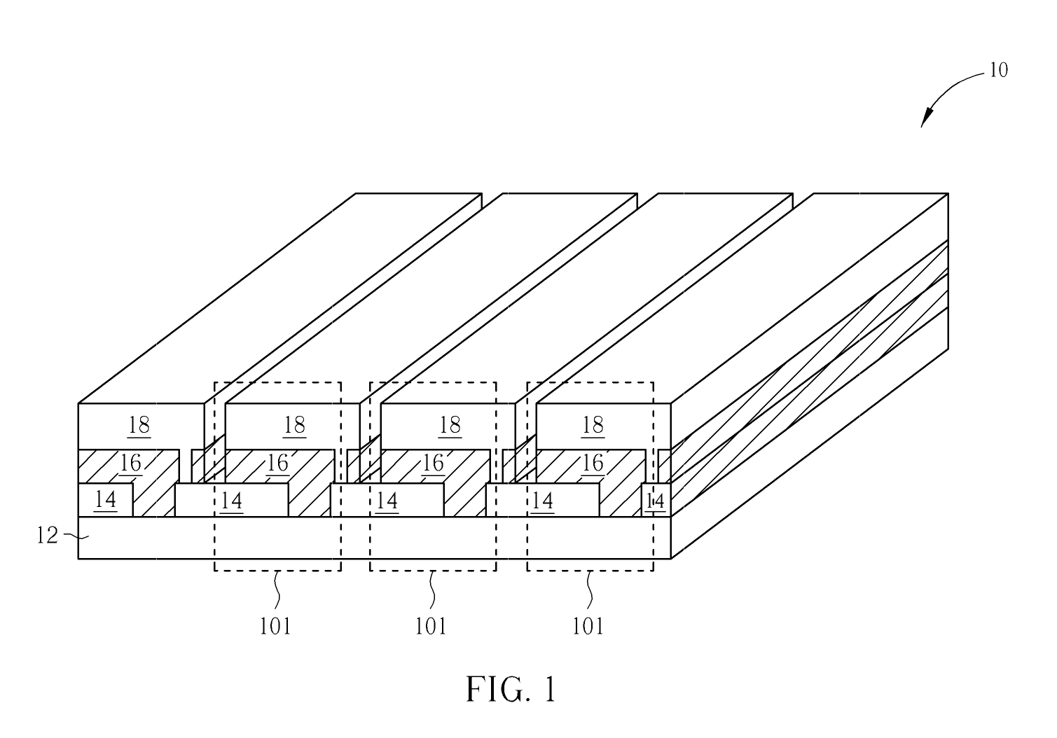

### DETAILED DESCRIPTION

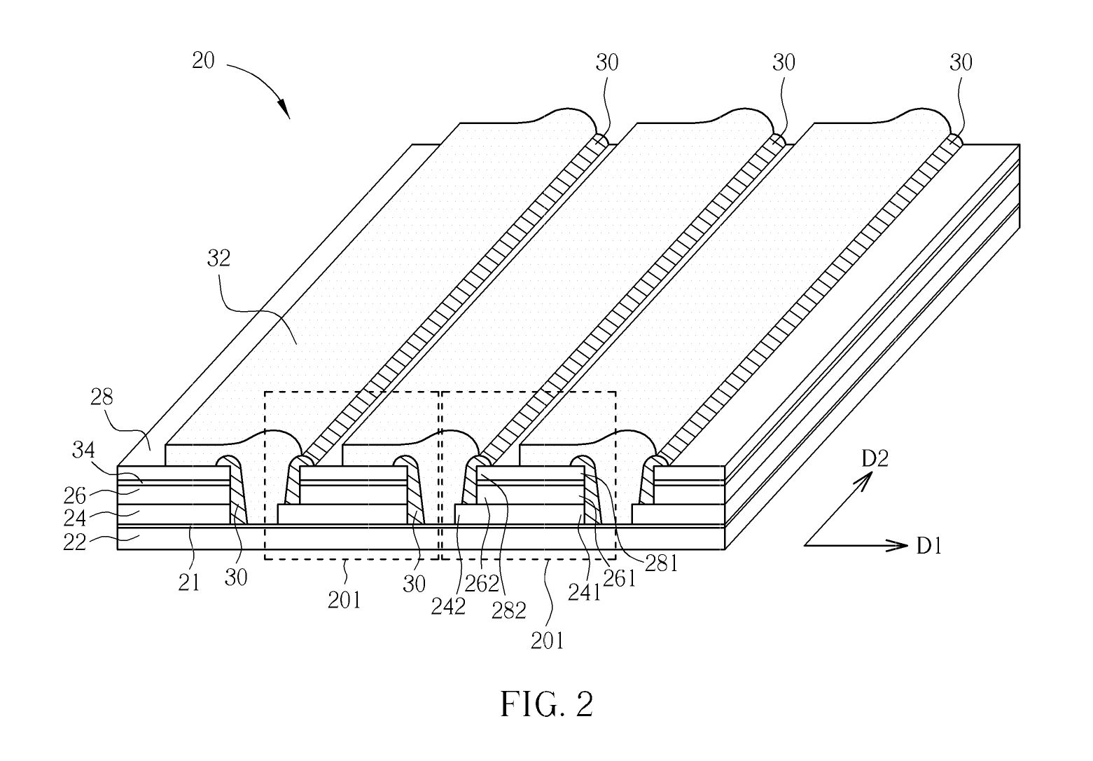

Please refer to FIG. 2. FIG. 2 is a diagram of a solar battery module 20 according to a preferred embodiment of the invention. The solar battery module 20 includes a substrate 22, a plurality of first striped electrodes 24 separately formed on the substrate 22, and a plurality of striped photoelectric transducing layers 26 respectively formed on the corresponding first striped electrode 24. The substrate 22 could be a transparent substrate or a flexible substrate. The flexible substrate could be selected from a group consisting of aluminum thin foil, stainless steel and polyimide material. It should be mentioned that a barrier layer 21 made of aluminum oxide, silicone nitride and silicon dioxide material could be formed on the substrate 22 as the substrate 22 is made of aluminum thin foil or stainless steel. The barrier layer 21 could isolate electric current. A width of each striped photoelectric transducing layer 26 along a first direction D1 is substantially equal to or smaller than a width of the corresponding first striped electrode 24 along the first direction D1. A first end 261 of each striped photoelectric transducing layer 26 could align with a first end 241 of the corresponding first striped electrode 24, and a second end 262 of parts of the striped photoelectric transducing layer 26 does not align with a second end 242 of the corresponding first striped electrode 24 to expose parts of the first striped electrode 24. As shown in FIG. 2, a step structure is formed by the second ends of the first striped electrode 24 and the corresponding striped photoelectric transducing layer 26, and the first end 261 of each striped photoelectric transducing layer 26 aligns with the first end 241 of the corresponding first striped electrode 24 in this embodiment.

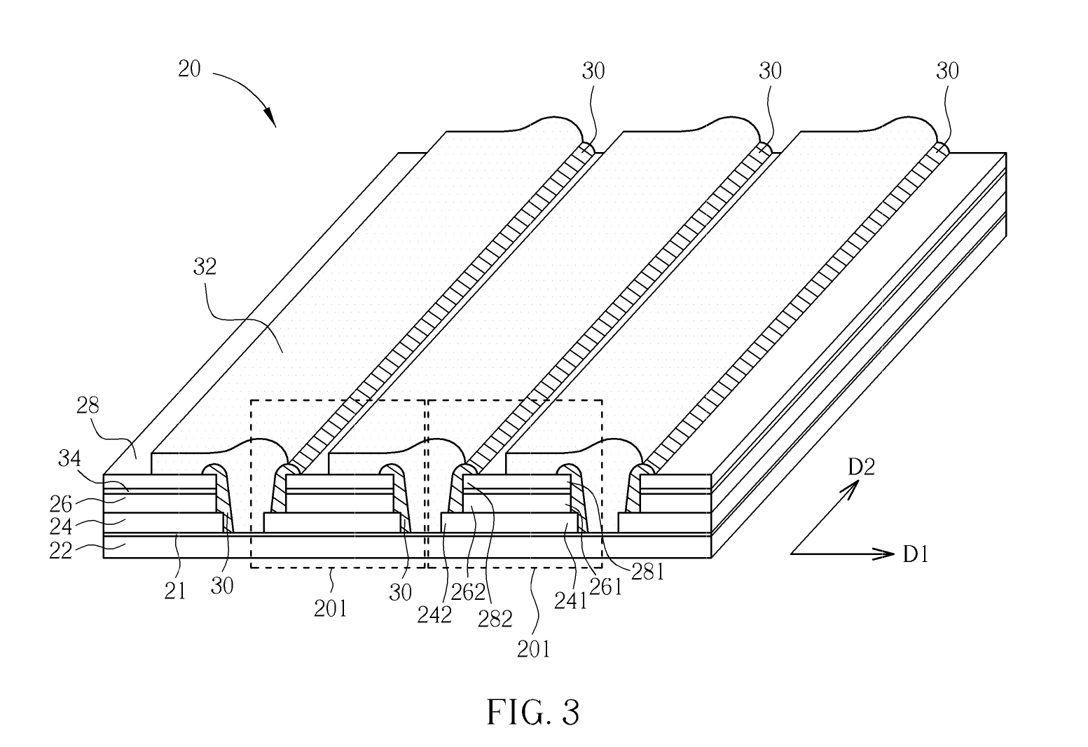

Please refer to FIG. 3. FIG. 3 is a diagram of the solar battery module 20 according to the other embodiment of the invention. As shown in FIG. 3, the first end 261 of each photoelectric transducing layer 26 could not align with the first end 241 of the corresponding first striped electrode 24. The solar battery module 20 further includes a plurality of second striped electrode 28 respectively formed on the corresponding striped photoelectric transducing layer 26. A first end 281 and a second end 282 of each second striped electrode 28 could respectively align with the first end 261 and the second end 262 of the corresponding striped photoelectric transducing layer 26. Similarly, the first end 281 and the second end 282 of each second striped electrode 28 could not align with the first end 261 and the second end 262 of the corresponding photoelectric transducing layer 26 (not shown in figures). In addition, the solar battery module 20 further includes a plurality of insulating layers 30 respectively formed between the adjacent first striped electrodes 24, the adjacent striped photoelectric transducing layers 26 and the adjacent second striped electrodes 28. Each insulating layer 30 covers the first end 241 of the corresponding first striped electrode 24, the first end 261 of the corresponding striped photoelectric transducing layer 26, and the first end 281 of the corresponding second striped electrode 28, and does not cover parts of the substrate 22 and the second end 242 of the corresponding first striped electrode 24.

The solar battery module 20 further includes a plurality of conducting layers 32 respectively formed between the adjacent insulating layers 30. Each conducting layer 32 contacts an upper surface of the second striped electrode 28 and the second end 242 of the adjacent first striped electrode 24, so that the plurality of first striped electrodes 24 and the plurality of second striped electrodes 28 are in series connection along the first direction D1, and an outputting voltage of the solar battery module 20 could be adjusted according to user's demand. The plurality of insulating layers 30 could be for preventing the conducting layer 32 from contacting lateral surfaces of the adjacent second striped electrodes, lateral surfaces of the adjacent striped photoelectric transducing layers 26, and the first end 241 of the adjacent first striped electrode 24. Furthermore, the solar battery module 20 could further include a buffer layer 34 disposed between the striped photoelectric transducing layer 26 and the second striped electrode 28.

Generally, the first striped electrode 24 could be made of molybdenum (Mo) material, the striped photoelectric transducing layer 26 could be made of copper indium gallium selenide (CIGS) material, the second striped electrode 28 could be made of aluminum zinc oxide (AZO) or tin-doped indium oxide (ITO) material, the insulating layer 30 could be made of insulating material, the conducting layer 32 could be made of conductive material, such as Colloidal Silver, and the buffer layer 34 could be made of zinc sulphide (ZnS) material and intrinsic zinc oxide (ZnO) material. Material of the substrate 22, the first striped electrode 24, the striped photoelectric transducing 26, the second striped electrode 28, and the buffer layer 34 are not limited to the above-mentioned embodiment, and depend on design demand.

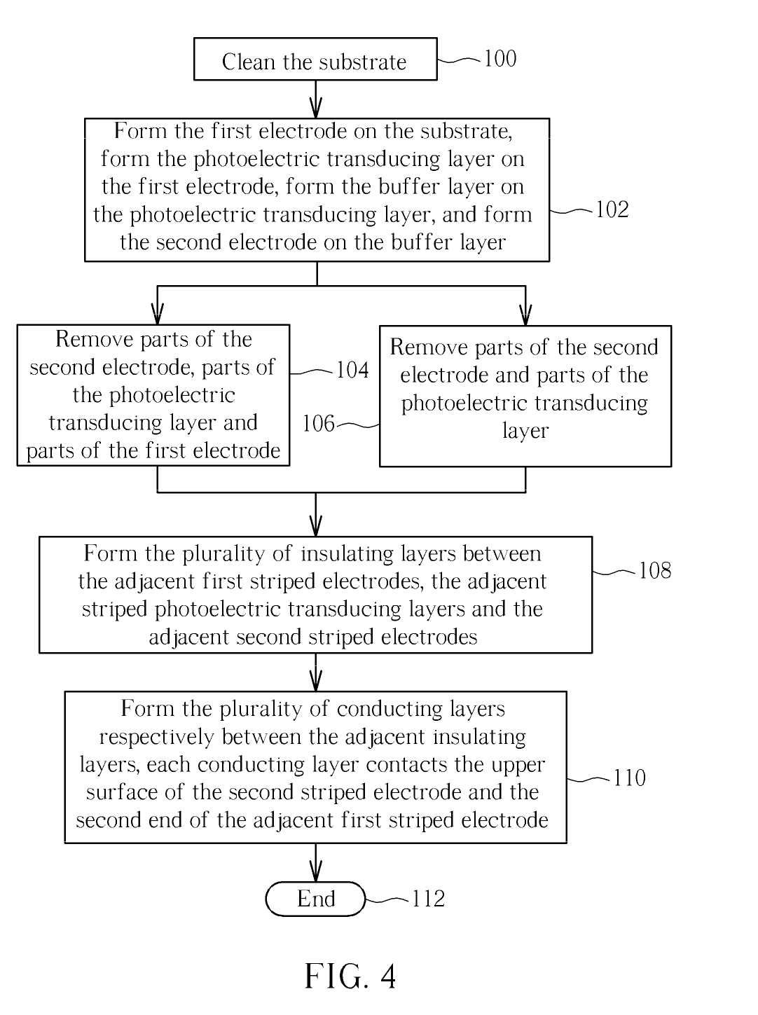

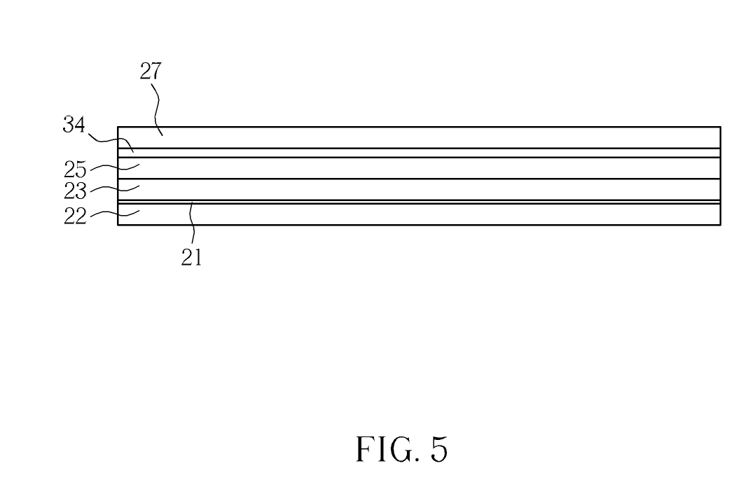

Please refer to FIG. 2 and FIG. 4 to FIG. 8. FIG. 4 is a flow chart of the method of manufacturing the solar battery module 20 according to the preferred embodiment of the invention. FIG. 5 to FIG. 9 are sectional views of the solar battery module 20 in different procedures along the first direction D1 according to the preferred embodiment of the invention. The method includes following steps:

Step 100: Clean the substrate 22.

Step 102: Form the first electrode 23 on the substrate 22, form the photoelectric transducing layer 25 on the first electrode 23, form the buffer layer 34 on the photoelectric transducing layer 25, and form the second electrode 27 on the buffer layer 34.

Step 104: Remove parts of the second electrode 27, parts of the photoelectric transducing layer 25 and parts of the first electrode 23.

Step 106: Remove parts of the second electrode 27 and parts of the photoelectric transducing layer 25.

Step 108: Form the plurality of insulating layers 30 between the adjacent first striped electrodes 24, the adjacent striped photoelectric transducing layers 26 and the adjacent second striped electrodes 28, wherein each insulating layer 30 covers the first end 241 of the corresponding first striped electrode 24, the first end 261 of the corresponding striped photoelectric transducing layer 26, and the first end 281 of the corresponding second striped electrode 28, and does not cover the parts of the substrate 22 and the second end 282 of the corresponding first striped electrode 24.

Step 110: Form the plurality of conducting layers 32 respectively between the adjacent insulating layers 30, each conducting layer 32 contacts the upper surface of the second striped electrode 28 and the second end 242 of the adjacent first striped electrode 24, so that the plurality of first striped electrodes 24 and the plurality of second striped electrode 28 are in series connection along the first direction D1, the plurality of insulating layers 30 prevent each conducting layer 32 from contacting the lateral surfaces of the adjacent second striped electrodes 28, the lateral surfaces of the adjacent striped photoelectric transducing layers 26, and the first end 241 of the adjacent first striped electrode 24.

Step 112: End.

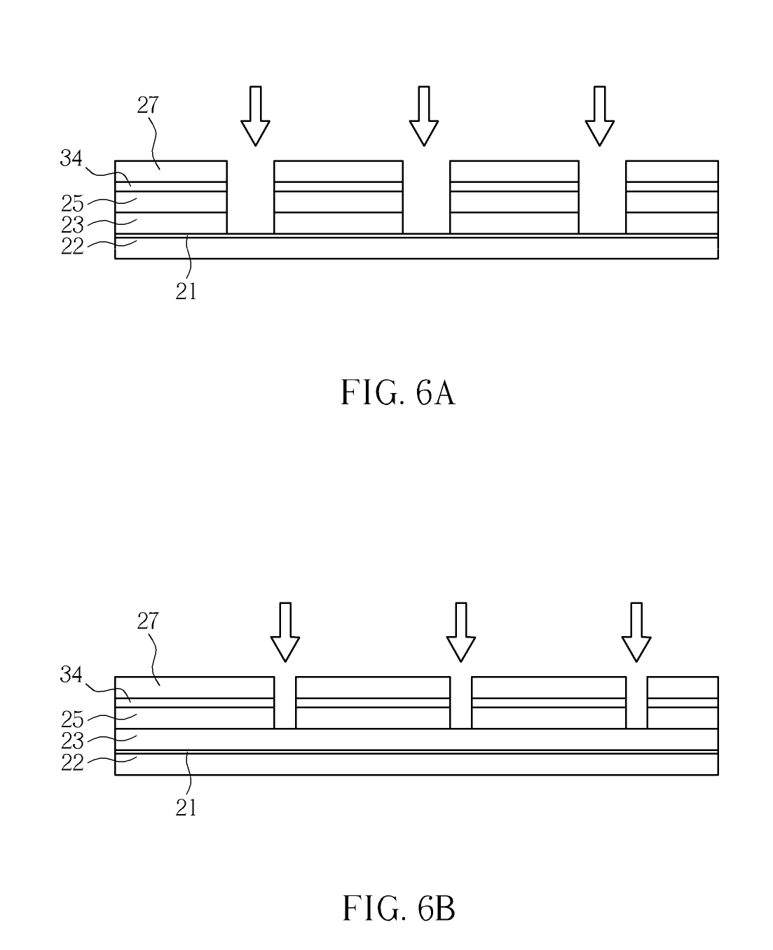

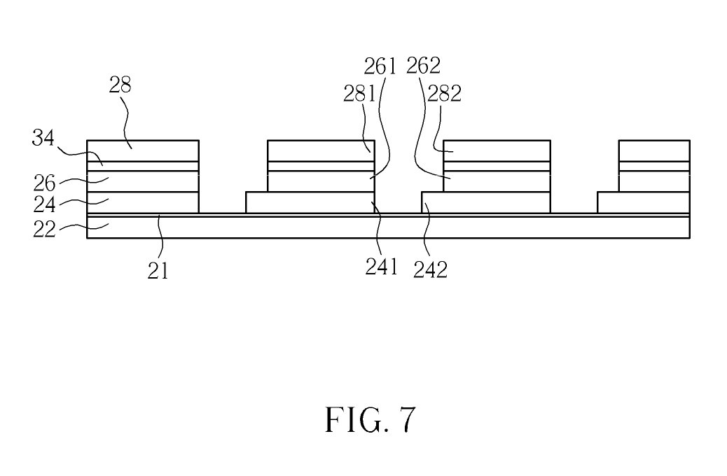

Detailed description of the method is introduced as follows, and step 100 to step 110 corresponds to FIG. 5, FIG. 6A, FIG. 7 to FIG. 9 respectively. First, as shown in FIG. 5, the substrate 22 is cleaned for preventing dirt from heaping on the substrate 22. Then, a barrier layer 21 is selectively formed on the substrate 22. The first electrode 23 made of the Mo material could be formed on the barrier layer 21 by sputtering or other technology, the photoelectric transducing layer 25 could be formed on the first electrode 23 by thin film deposition method or other technology, the buffer layer 34 made of the ZnS material and the intrinsic ZnO material could be formed on the photoelectric transducing layer 25, and the second electrode 27 could be formed on the buffer layer 34. As shown in FIG. 6A, the parts of the second electrode 27, the parts of the photoelectric transducing layer 25 and the parts of the first electrode 23 could be simultaneously removed along the first direction D1 by the scraper technology, the laser technology or other removing technology, so as to expose the barrier layer 21 (the substrate 22 is covered by the barrier layer 21 and is not exposed), so that a sunken slot is formed as an arrow shown in FIG. 6A. After, as shown in FIG. 7, parts of the second electrode 27 and parts of the photoelectric transducing layer 25 are removed again to form the plurality of first striped electrodes 24, the plurality of striped photoelectric transducing layers 26 and the plurality of second striped electrodes 34. Meanwhile, the first end 241 and the second end 242 of each first striped electrode 24, the first end 261 and the second end 262 of each striped photoelectric transducing layer 26, and the first end 281 and the second end 282 of each second striped electrode 28 are exposed inside the sunken slot, and a bottom of the sunken slot can be a step structure.

Step 104 and step 106 of the method of the invention can be exchanged for another embodiment. For example, the second electrode 27 and the photoelectric transducing layer 25 could be removed to expose the parts of the first electrode 23, as shown in FIG. 5, FIG. 6B and FIG. 7, and then the parts of the second electrode 27, the parts of the photoelectric transducing layer 25 and the parts of the first electrode 23 could be removed to form the plurality of first striped electrodes 24, the plurality of striped photoelectric transducing layers 26 and the plurality of second striped electrodes 34. In addition, an apparatus having laser cutting function and mechanical scraping function could be utilized in the invention for simultaneously executing step 104 and step 106, sequence of the method is designed according to apparatus, and detailed description is omitted herein for simplicity.

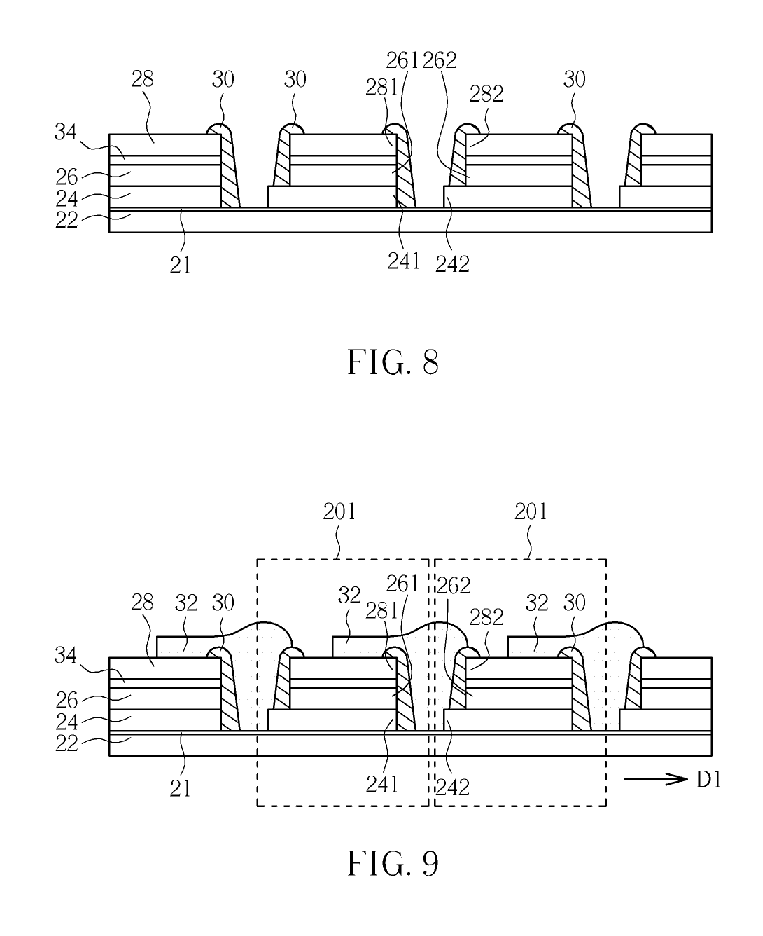

As shown in FIG. 8 and FIG. 9, the plurality of insulating layers 30 could be formed between the adjacent first striped electrodes 24, the adjacent striped photoelectric transducing layers 26 and the adjacent second striped electrodes 28. Each insulating layer 30 covers the first end 241 of the corresponding first striped electrode 24, the first end 261 of the corresponding striped photoelectric transducing layer 26, and the first end 281 of the corresponding second striped electrode 28, and does not cover the parts of the substrate 22 and the second end 242 of the corresponding first striped electrode 24. Final, the plurality of conducting layers 32 could be formed between the adjacent insulating layers 30. For example, the plurality of conducting layers 32 could be formed by screen printing technology. Each conducting layer 32 contacts the upper surface of the second striped electrode 28 and the second end 242 of the adjacent first striped electrode 24, so the plurality of first striped electrodes 24 and the plurality of second striped electrodes 28 can be in series connection along the first direction D1. The solar battery module 20 can include a plurality of solar batteries 201, and the adjacent solar batteries 201 can be in parallel connection by the conducting layer 32. The insulating layer 30 can prevent the conducting layer 32 from contacting the lateral surfaces of the adjacent second striped electrodes 28, the lateral surfaces of the adjacent striped photoelectric transducing layers 26, and the first end 241 of the adjacent first striped electrode 24, so as to prevent the solar battery module 20 from short. In addition, the buffer layer 34 is a thin film having preferred photoelectric property, and can be for increasing the photoelectric transducing efficiency and the electricity generating efficiency of the solar battery module 20. Material and manufacturing procedures of the buffer layer 34 is not limited to the above-mentioned embodiment, which is a selectable procedure, and it depends on design demand. Generally, the thin film deposition could be realized by co-evaporation, vacuum sputter, and selenization methods to achieve preferable photoelectric transducing efficiency of the CIGS film.

In conclusion, the solar battery module 20 is composed of the plurality of solar batteries 201, and the plurality of solar batteries 201 are in series connection and parallel connection for achieving the voltage and the current which conforms to user demands. The plurality of sunken slots is formed on the solar battery module 20 of the invention for forming the plurality of striped solar batteries 201, and the insulating layers 30 and the conducting layer 32 are formed inside the sunken slots for electrically connecting the adjacent solar batteries 201. Therefore, the solar battery module 20 of the invention is not necessary to be cut for forming the plurality of solar batteries 201 electrically connected with one another by string and lay-up method. The effective photoelectric transducing area of the solar battery module 20 can be controlled easily, and the solar batteries 201 can be in series connection and parallel connection as needed, which means the solar battery module 20 with heavy current and heavy voltage can be customized according to user's demand.

Comparing to the prior art, the plurality of solar batteries can be formed by segmenting the solar battery module of the invention directly. Two insulating layers can be respectively disposed on edges of each solar battery adjacent to the other solar batteries, so that the conducting layer does not contact the adjacent conducting layer and the electrode for preventing short in manufacturing procedure by protection of the insulating layer, and each solar battery can be electrically connected to the adjacent solar battery by the conducting layer. Thus, the solar battery module with smaller gaps between the solar batteries can be manufactured in the invention without the expensive alignment apparatus. The effective photoelectric transducing area of the solar battery module is controlled easily by the manufacturing method of the invention, so as to manufacture the solar battery module with the heavy current and the heavy voltage according to user's demand.

Those skilled in the art will readily observe that numerous modifications and alterations of the device and method may be made while retaining the teachings of the invention.

What is claimed is:

1. A solar battery module comprising:
a substrate;
a plurality of first striped electrodes separately formed on the substrate;
a plurality of striped photoelectric transducing layers respectively formed on the corresponding first striped electrode, a width of each striped photoelectric transducing layer along a first direction being substantially smaller than a width of the corresponding first striped electrode along the first direction;
a plurality of second striped electrodes respectively formed on the corresponding striped photoelectric transducing layer;
a plurality of insulating layers respectively formed between the adjacent first striped electrodes, the adjacent striped photoelectric transducing layers and the adjacent second striped electrodes, the insulating layer covering a first end of the corresponding first striped electrode, a first end and a second end of the corresponding striped photoelectric transducing layer, and a first end and a second end of the corresponding second striped electrode, and the insulating layer not covering parts of the substrate and a second end of the corresponding first striped electrode; and
a plurality of conducting layers respectively formed between the adjacent insulating layers, each conducting layer contacting an upper surface of the second striped electrode and the adjacent first striped electrode, so that the first striped electrode and the second striped electrode are in series connection along the first direction.

2. The solar battery module of claim 1, wherein the first end of each striped photoelectric transducing layer aligns with the first end of the corresponding first striped electrode, and the second end of each striped photoelectric transducing layer does not align with the second end of the corresponding first striped electrode to expose the parts of the first striped electrode.

3. The solar battery module of claim 2, wherein the first end and the second end of each second striped electrode respectively align with the first end and the second end of the corresponding striped photoelectric transducing layer.

4. The solar battery module of claim 1, wherein the first end and the second end of each second striped electrode respectively align with the first end and the second end of the corresponding striped photoelectric transducing layer.

5. The solar battery module of claim 1, further comprising:
a buffer layer formed between the striped photoelectric transducing layer and the second striped electrode, the buffer layer being made of zinc sulphide material and intrinsic zinc oxide material.

6. The solar battery module of claim 1, wherein the substrate is a flexible substrate, and the flexible substrate is selected from a group consisting of aluminum thin foil and stainless steel.

7. The solar battery module of claim 6, wherein the solar battery module further comprises a barrier layer disposed between the substrate and the first striped electrode, and the barrier layer is selected from a group consisting of silicon dioxide material, aluminum oxide material, silicone nitride material, and combination thereof.

8. The solar battery module of claim 1, wherein the substrate is a flexible substrate, and the flexible substrate is made of polyimide material.

9. The solar battery module of claim 1, wherein the first striped electrode is made of molybdenum material.

10. The solar battery module of claim 1, wherein the striped photoelectric transducing layer is made of copper indium gallium selenide material.

11. The solar battery module of claim 1, wherein the second striped electrode is a transparent conductive layer made of aluminum zinc oxide or tin-doped indium oxide material.

12. A method of manufacturing a solar battery module comprising:
forming a first electrode layer on a substrate;
forming a photoelectric transducing layer on the first electrode layer;
forming a second electrode layer on the photoelectric transducing layer;
removing parts of the second electrode layer, parts of the photoelectric transducing layer and parts of the first electrode layer, so as to form a plurality of first striped electrodes, a plurality of striped photoelectric transducing layers and a plurality of second striped electrodes separately arranged in parallel along a first direction, and to expose parts of the substrate and parts of the first striped electrode;
forming a plurality of insulating layers between the adjacent first striped electrodes, the adjacent striped photoelectric transducing layers and the adjacent second striped electrodes, so that the insulating layer covers a first end of the corresponding first striped electrode, a first end and a second end of the corresponding striped photoelectric transducing layer, and a first end and a second end of the corresponding second striped electrode, and the insulating layer does not cover parts of the substrate and a second end of the corresponding first striped electrode; and
forming a plurality of conducting layers respectively between the adjacent insulating layers, each conducting layer contacting an upper surface of the second striped electrode and the adjacent first striped electrode, so that the first striped electrode and the second striped electrode are in series connection along the first direction.

13. The method of claim 12, further comprising:
cleaning the substrate before forming the first electrode layer on the substrate.

14. The method of claim 12, further comprising:
forming a buffer layer between the photoelectric transducing layer and the second electrode layer.

15. The method of claim 12, further comprises:
removing the parts of the second electrode layer and the parts of the photoelectric transducing layer by a scraper, and simultaneously removing the parts of the second electrode layer, the parts of the photoelectric transducing layer and the parts of the first electrode layer by a laser, so as to expose the parts of the substrate and the parts of the first striped electrode.

16. The method of claim 12, further comprises:
removing the parts of the second electrode layer and the parts of the photoelectric transducing layer by a scraper to expose the parts of the first striped electrode layer, and then removing the parts of the second electrode layer, the parts of the photoelectric transducing layer and the parts of the first electrode layer by a laser to expose the parts of the substrate.

17. The method of claim 12, further comprises:
removing the parts of the second electrode layer, the parts of the photoelectric transducing layer and the parts of the first electrode layer by a laser to expose the parts of the substrate, and then removing the parts of the second electrode layer and the parts of the photoelectric transducing layer by a scraper to expose the parts of the first striped electrode.
